(19) United States
(12) Patent Application Publication
(10) Pub. No.: US 2025/0140232 A1
(43) Pub. Date: May 1, 2025

(54) METHOD AND APPARATUS FOR NEURAL NETWORK AUGMENTED KALMAN FILTER FOR ACOUSTIC HOWLING SUPPRESSION

(71) Applicant: TENCENT AMERICA LLC, Palo Alto, CA (US)

(72) Inventors: Hao ZHANG, Palo Alto, CA (US); Meng Yu, Palo Alto, CA (US); Dong Yu, Palo Alto, CA (US)

(73) Assignee: TENCENT AMERICA LLC, Palo Alto, CA (US)

(21) Appl. No.: 18/494,302

(22) Filed: Oct. 25, 2023

(51) Int. Cl. G10K 11/178; G06N 3/0442; G06N 3/08; H03H 17/02

(52) U.S. Cl. CPC G10K 11/1781; G06N 3/0442; G06N 3/08; H03H 17/0257

(57) ABSTRACT

A method performed by at least one processor of an acoustic howling suppression (AHS) system includes receiving, from an input source device, an audio signal. The method includes refining one or more parameters of a Kalman filter based on one or more neural networks. The method includes filtering the audio signal using the Kalman filter with the one or more refined parameters of the Kalman filter to reduce acoustic howling included in the audio signal.

### FIELD

The disclosure generally relates to acoustic howling suppression (AHS), and, in particular, to a method and apparatus for an augmented Kalman filter for AHS.

### BACKGROUND

Acoustic howling suppression (AHS) is a critical challenge in audio communication systems. Acoustic howling is a phenomenon that frequently arises in audio systems such as karaoke systems and public addressing systems where the amplified sound from the loudspeaker is captured by the microphone and subsequently re-amplified recursively. This phenomenon creates an internal positive feedback loop within audio systems, leading to an unpleasant howling sound that reinforces specific frequency components, which not only jeopardizes the proper functioning of equipment, but also poses potential risks to human auditory health.

Various techniques have been explored to suppress howling including gain control, notch filter, and adaptive feedback control (AFC). Notably, AFC methods leverage adaptive filtering to suppress howling through continuous adjustments of filter coefficients driven by iterative feedback. The real-time adaptation of AFC methods breaks the positive feedback loop and results in AHS suppression. However, such methods have shown disadvantageous sensitivity to control parameters and cannot effectively manage the nonlinearity introduced by amplifiers and loudspeakers.

Deep-learning-based approaches have been explored to solve the AHS problem. For example, a model based on convolutional recurrent neural network was introduced for howling detection. A deep neural network (DNN) as an adaptive filter has been used in the time-frequency domain to suppress howling noise from a speech signal. A deep learning framework, called DeepMFC, was introduced to address marginal stability issues of acoustic feedback systems. However, the data used for training is generated offline in a closed-loop system without AHS processing. This leads to a mismatch during streaming inference, as AHS processing is continuously integrated, thereby influencing the input stream of the AHS processing. DeepAHS may be used to leverage the teacher-forcing strategy for AHS. HybridAHS, which incorporates filtering by augmenting its output as network input, may be used for AHS. However, for both of these methods, the discrepancy between training and real-time streaming inference still exists.

### SUMMARY

According to one or more embodiments, a method performed by at least one processor of an acoustic howling suppression (AHS) system comprises receiving, from an input source device, an audio signal. The method further comprises refining one or more parameters of a Kalman filter based on one or more neural networks. The method further comprises filtering the audio signal using the Kalman filter with the one or more refined parameters of the Kalman filter to reduce acoustic howling included in the audio signal.

According to one or more embodiments, an acoustic howling suppression (AHS) system, comprises at least one memory configured to store program code and at least one processor configured to read the program code and operate as instructed by the program code. The program code comprises receiving code configured to cause the at least one processor to receive, from an input source device, an audio signal. The program further comprises refining code configured to cause the at least one processor to refine one or more parameters of a Kalman filter based on one or more neural networks. The program code further comprises filtering code configured to cause the at least one processor to filter the audio signal using the Kalman filter with the one or more refined parameters of the Kalman filter to reduce acoustic howling included in the audio signal.

According to one or more embodiments, a non-transitory computer readable medium having instructions stored therein, which when executed by a processor in an acoustic howling suppression (AHS) system cause the processor to execute a method comprising receiving, from an input source device, an audio signal. The method further comprises refining one or more parameters of a Kalman filter based on one or more neural networks. filtering the audio signal using the Kalman filter with the one or more refined parameters of the Kalman filter to reduce acoustic howling included in the audio signal.

### BRIEF DESCRIPTION OF THE DRAWINGS

Further features, the nature, and various advantages of the disclosed subject matter will be more apparent from the following detailed description and the accompanying drawings in which:

FIG. 1 is a diagram of an environment in which methods, apparatuses, and systems described herein may be implemented, according to embodiments.

FIG. 2 is a block diagram of example components of one or more devices of FIG. 1.

FIG. 3 is a diagram of an acoustic amplification system with a NeuralKalmanAHS model according to embodiments.

FIG. 4 is a flowchart of an example process for acoustic howling suppression (AHS) using the NeuralKalmanAHS model, according to embodiments.

### DETAILED DESCRIPTION

The following detailed description of example embodiments refers to the accompanying drawings. The same reference numbers in different drawings may identify the same or similar elements.

The foregoing disclosure provides illustration and description, but is not intended to be exhaustive or to limit the implementations to the precise form disclosed. Modifications and variations are possible in light of the above disclosure or may be acquired from practice of the implementations. Further, one or more features or components of one embodiment may be incorporated into or combined with another embodiment (or one or more features of another embodiment). Additionally, in the flowcharts and descriptions of operations provided below, it is understood that one or more operations may be omitted, one or more operations may be added, one or more operations may be performed simultaneously (at least in part), and the order of one or more operations may be switched.

It will be apparent that systems and/or methods, described herein, may be implemented in different forms of hardware, firmware, or a combination of hardware and software. The actual specialized control hardware or software code used to implement these systems and/or methods is not limiting of the implementations. Thus, the operation and behavior of the systems and/or methods were described herein without reference to specific software code—it being understood that software and hardware may be designed to implement the systems and/or methods based on the description herein.

Even though particular combinations of features are recited in the claims and/or disclosed in the specification, these combinations are not intended to limit the disclosure of possible implementations. In fact, many of these features may be combined in ways not specifically recited in the claims and/or disclosed in the specification. Although each dependent claim listed below may directly depend on only one claim, the disclosure of possible implementations includes each dependent claim in combination with every other claim in the claim set.

No element, act, or instruction used herein should be construed as critical or essential unless explicitly described as such. Also, as used herein, the articles “a” and “an” are intended to include one or more items, and may be used interchangeably with “one or more.” Where only one item is intended, the term “one” or similar language is used. Also, as used herein, the terms “has,” “have,” “having,” “include,” “including,” or the like are intended to be open-ended terms. Further, the phrase “based on” is intended to mean “based, at least in part, on” unless explicitly stated otherwise. Furthermore, expressions such as “at least one of [A] and [B]” or “at least one of [A] or [B]” are to be understood as including only A, only B, or both A and B.

Reference throughout this specification to “one embodiment,” “an embodiment,” or similar language means that a particular feature, structure, or characteristic described in connection with the indicated embodiment is included in at least one embodiment of the present solution. Thus, the phrases “in one embodiment”, “in an embodiment,” and similar language throughout this specification may, but do not necessarily, all refer to the same embodiment.

Furthermore, the described features, advantages, and characteristics of the present disclosure may be combined in any suitable manner in one or more embodiments. One skilled in the relevant art will recognize, in light of the description herein, that the present disclosure may be practiced without one or more of the specific features or advantages of a particular embodiment. In other instances, additional features and advantages may be recognized in certain embodiments that may not be present in all embodiments of the present disclosure.

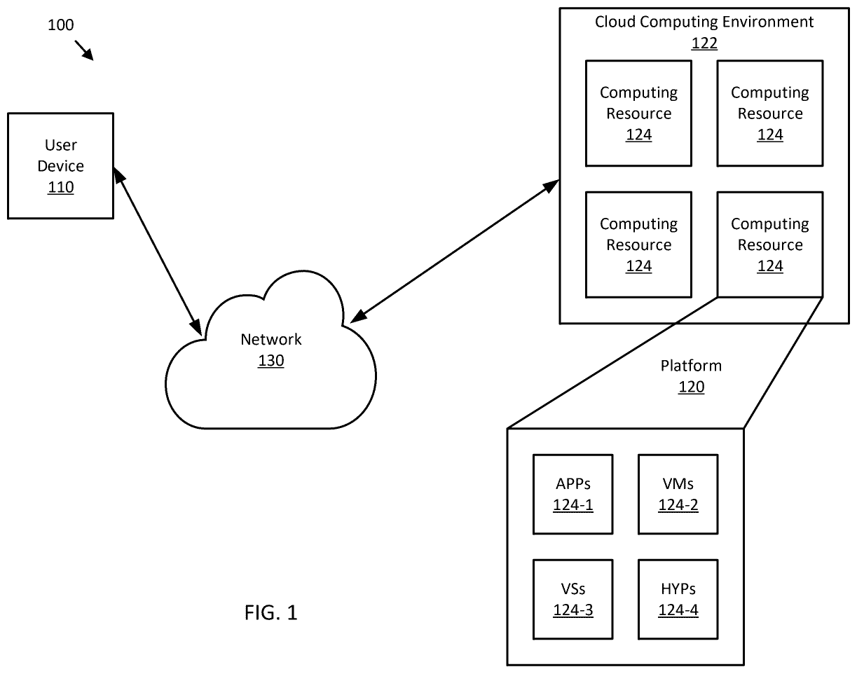

FIG. 1 is a diagram of an environment 100 in which methods, apparatuses, and systems described herein may be implemented, according to embodiments. As shown in FIG. 1, the environment 100 may include a user device 110, a platform 120, and a network 130. Devices of the environment 100 may interconnect via wired connections, wireless connections, or a combination of wired and wireless connections.

The user device 110 includes one or more devices capable of receiving, generating, storing, processing, and/or providing information associated with platform 120. For example, the user device 110 may include a computing device (e.g., a desktop computer, a laptop computer, a tablet computer, a handheld computer, a smart speaker, a server, etc.), a mobile phone (e.g., a smart phone, a radiotelephone, etc.), a wearable device (e.g., a pair of smart glasses or a smart watch), or a similar device. In some implementations, the user device 110 may receive information from and/or transmit information to the platform 120.

The platform 120 includes one or more devices as described elsewhere herein. In some implementations, the platform 120 may include a cloud server or a group of cloud servers. In some implementations, the platform 120 may be designed to be modular such that software components may be swapped in or out depending on a particular need. As such, the platform 120 may be easily and/or quickly reconfigured for different uses.

In some implementations, as shown, the platform 120 may be hosted in a cloud computing environment 122. Notably, while implementations described herein describe the platform 120 as being hosted in the cloud computing environment 122, in some implementations, the platform 120 may not be cloud-based (i.e., may be implemented outside of a cloud computing environment) or may be partially cloud-based.

The cloud computing environment 122 includes an environment that hosts the platform 120. The cloud computing environment 122 may provide computation, software, data access, storage, etc. services that do not require end-user (e.g. the user device 110) knowledge of a physical location and configuration of system(s) and/or device(s) that hosts the platform 120. As shown, the cloud computing environment 122 may include a group of computing resources 124 (referred to collectively as “computing resources 124” and individually as “computing resource 124”).

The computing resource 124 includes one or more personal computers, workstation computers, server devices, or other types of computation and/or communication devices. In some implementations, the computing resource 124 may host the platform 120. The cloud resources may include compute instances executing in the computing resource 124, storage devices provided in the computing resource 124, data transfer devices provided by the computing resource 124, etc. In some implementations, the computing resource 124 may communicate with other computing resources 124 via wired connections, wireless connections, or a combination of wired and wireless connections.

As further shown in FIG. 1, the computing resource 124 includes a group of cloud resources, such as one or more applications (APPs) 124-1, one or more virtual machines (VMs) 124-2, virtualized storage (VSs) 124-3, one or more hypervisors (HYPs) 124-4, or the like.

The application 124-1 includes one or more software applications that may be provided to or accessed by the user device 110 and/or the platform 120. The application 124-1 may eliminate a need to install and execute the software applications on the user device 110. For example, the application 124-1 may include software associated with the platform 120 and/or any other software capable of being provided via the cloud computing environment 122. In some implementations, one application 124-1 may send/receive information to/from one or more other applications 124-1, via the virtual machine 124-2.

The virtual machine 124-2 includes a software implementation of a machine (e.g. a computer) that executes programs like a physical machine. The virtual machine 124-2 may be either a system virtual machine or a process virtual machine, depending upon use and degree of correspondence to any real machine by the virtual machine 124-2. A system virtual machine may provide a complete system platform that supports execution of a complete operating system (OS). A process virtual machine may execute a single program, and may support a single process. In some implementations, the virtual machine 124-2 may execute on behalf of a user (e.g. the user device 110), and may manage infrastructure of the cloud computing environment 122, such as data management, synchronization, or long-duration data transfers.

The virtualized storage 124-3 includes one or more storage systems and/or one or more devices that use virtualization techniques within the storage systems or devices of the computing resource 124. In some implementations, within the context of a storage system, types of virtualizations may include block virtualization and file virtualization. Block virtualization may refer to abstraction (or separation) of logical storage from physical storage so that the storage system may be accessed without regard to physical storage or heterogeneous structure. The separation may permit administrators of the storage system flexibility in how the administrators manage storage for end users. File virtualization may eliminate dependencies between data accessed at a file level and a location where files are physically stored. This may enable optimization of storage use, server consolidation, and/or performance of non-disruptive file migrations.

The hypervisor 124-4 may provide hardware virtualization techniques that allow multiple operating systems (e.g. “guest operating systems”) to execute concurrently on a host computer, such as the computing resource 124. The hypervisor 124-4 may present a virtual operating platform to the guest operating systems, and may manage the execution of the guest operating systems. Multiple instances of a variety of operating systems may share virtualized hardware resources.

The network 130 includes one or more wired and/or wireless networks. For example, the network 130 may include a cellular network (e.g. a fifth generation (5G) network, a long-term evolution (LTE) network, a third generation (3G) network, a code division multiple access (CDMA) network, etc.), a public land mobile network (PLMN), a local area network (LAN), a wide area network (WAN), a metropolitan area network (MAN), a telephone network (e.g. the Public Switched Telephone Network (PSTN)), a private network, an ad hoc network, an intranet, the Internet, a fiber optic-based network, or the like, and/or a combination of these or other types of networks.

The number and arrangement of devices and networks shown in FIG. 1 are provided as an example. In practice, there may be additional devices and/or networks, fewer devices and/or networks, different devices and/or networks, or differently arranged devices and/or networks than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g. one or more devices) of the environment 100 may perform one or more functions described as being performed by another set of devices of the environment 100.

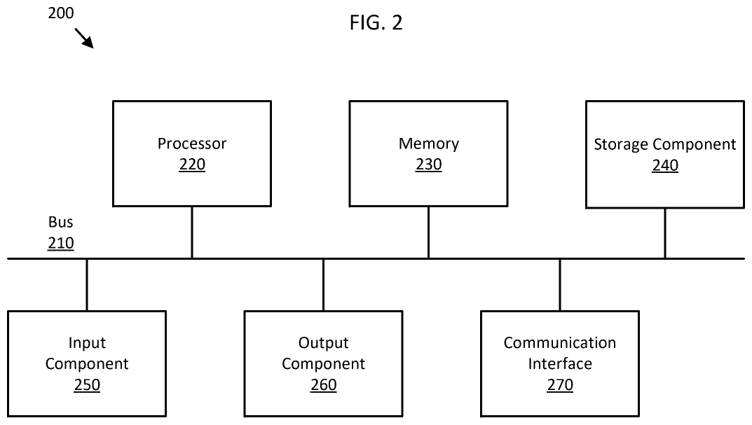

FIG. 2 is a block diagram of example components of one or more devices of FIG. 1. The device 200 may correspond to the user device 110 and/or the platform 120. As shown in FIG. 2, the device 200 may include a bus 210, a processor 220, a memory 230, a storage component 240, an input component 250, an output component 260, and a communication interface 270.

The bus 210 includes a component that permits communication among the components of the device 200. The processor 220 is implemented in hardware, firmware, or a combination of hardware and software. The processor 220 is a central processing unit (CPU), a graphics processing unit (GPU), an accelerated processing unit (APU), a microprocessor, a microcontroller, a digital signal processor (DSP), a field-programmable gate array (FPGA), an application-specific integrated circuit (ASIC), or another type of processing component. In some implementations, the processor 220 includes one or more processors capable of being programmed to perform a function. The memory 230 includes a random access memory (RAM), a read only memory (ROM), and/or another type of dynamic or static storage device (e.g. a flash memory, a magnetic memory, and/or an optical memory) that stores information and/or instructions for use by the processor 220.

The storage component 240 stores information and/or software related to the operation and use of the device 200. For example, the storage component 240 may include a hard disk (e.g. a magnetic disk, an optical disk, a magneto-optic disk, and/or a solid state disk), a compact disc (CD), a digital versatile disc (DVD), a floppy disk, a cartridge, a magnetic tape, and/or another type of non-transitory computer-readable medium, along with a corresponding drive.

The input component 250 includes a component that permits the device 200 to receive information, such as via user input (e.g. a touch screen display, a keyboard, a keypad, a mouse, a button, a switch, and/or a microphone). Additionally, or alternatively, the input component 250 may include a sensor for sensing information (e.g. a global positioning system (GPS) component, an accelerometer, a gyroscope, and/or an actuator). The output component 260 includes a component that provides output information from the device 200 (e.g. a display, a speaker, and/or one or more light-emitting diodes (LEDs)).

The communication interface 270 includes a transceiver-like component (e.g., a transceiver and/or a separate receiver and transmitter) that enables the device 200 to communicate with other devices, such as via a wired connection, a wireless connection, or a combination of wired and wireless connections. The communication interface 270 may permit the device 200 to receive information from another device and/or provide information to another device. For example, the communication interface 270 may include an Ethernet interface, an optical interface, a coaxial interface, an infrared interface, a radio frequency (RF) interface, a universal serial bus (USB) interface, a Wi-Fi interface, a cellular network interface, or the like.

The device 200 may perform one or more processes described herein. The device 200 may perform these processes in response to the processor 220 executing software instructions stored by a non-transitory computer-readable medium, such as the memory 230 and/or the storage component 240. A computer-readable medium is defined herein as a non-transitory memory device. A memory device includes memory space within a single physical storage device or memory space spread across multiple physical storage devices.

Software instructions may be read into the memory 230 and/or the storage component 240 from another computer-readable medium or from another device via the communication interface 270. When executed, software instructions stored in the memory 230 and/or the storage component 240 may cause the processor 220 to perform one or more processes described herein. Additionally, or alternatively, hardwired circuitry may be used in place of or in combination with software instructions to perform one or more processes described herein. Thus, implementations described herein are not limited to any specific combination of hardware circuitry and software.

The number and arrangement of components shown in FIG. 2 are provided as an example. In practice, the device 200 may include additional components, fewer components, different components, or differently arranged components than those shown in FIG. 2. Additionally, or alternatively, a set of components (e.g. one or more components) of the device 200 may perform one or more functions described as being performed by another set of components of the device 200.

Embodiments of the present disclosure are directed to leveraging the power of neural networks (NN) to enhance the performance of a Kalman filter based algorithms for acoustic howling suppression (AHS). According to one or more embodiments, one or more NN modules are inserted into the Kalman filter, enabling the estimation of reference signals and covariance metrics for the Kalman filter, thereby obtaining improved AHS performance. The NN significantly enhances estimation of a reference signal and covariance matrices. As a result, the embodiments of the present disclosure achieve improved AHS performance compared to standalone NN or Kalman filter methods.

NN-augmented adaptive filtering approaches, which potentially introduce less distortion, have been explored in the context of AEC. Deep Adaptive AEC employs NN modules to estimate the nonlinear reference and the step size in a normalized least mean square (NLMS) algorithm, which shows improved performance compared to fully DNN-based baselines in time-varying acoustic environments. Prior research by the Applicant has integrated NN modules into a frequency-domain Kalman filter (FDKF) for estimating the nonlinear reference signal and a nonlinear transition function, which significantly improves the performance of FDKF and outperforms the NLMS-based Deep Adaptive AEC model. The Applicant has determined that exclusively employing NNs to estimate Kalman filter components does not necessarily yield performance improvements. However, Applicant has determined that leveraging NNs to estimate absent or approximated components within the Kalman filter algorithm has demonstrated considerable improvements, which leads to significantly improved AHS performance.

According to one or more embodiments, an NN augmented Kalman filter for AHS (NeuralKalmanAHS) is implemented for AHS. In one or more examples, the NeuralKalmanAHS incorporates NN modules into the frequency-domain Kalman filter, optimizing reference signal refinement and covariance matrix estimation. The NeuralKalmanAHS may be trained in a streaming mode that aligns with a streaming inference framework, where AHS models are evaluated in recurrent and real-world settings, thereby eliminating potential mismatch issues. According to one or more embodiments, a howling detection strategy may be implemented during training to ensure model convergence, thereby allowing successful model training even in challenging acoustic howling scenarios. Ablation studies indicate that streaming training ensures robustness of NeuralKalmanAHS against acoustic howling, even with lightweight models focused solely on covariance estimation, while reference signal refinement substantially boosts performance.

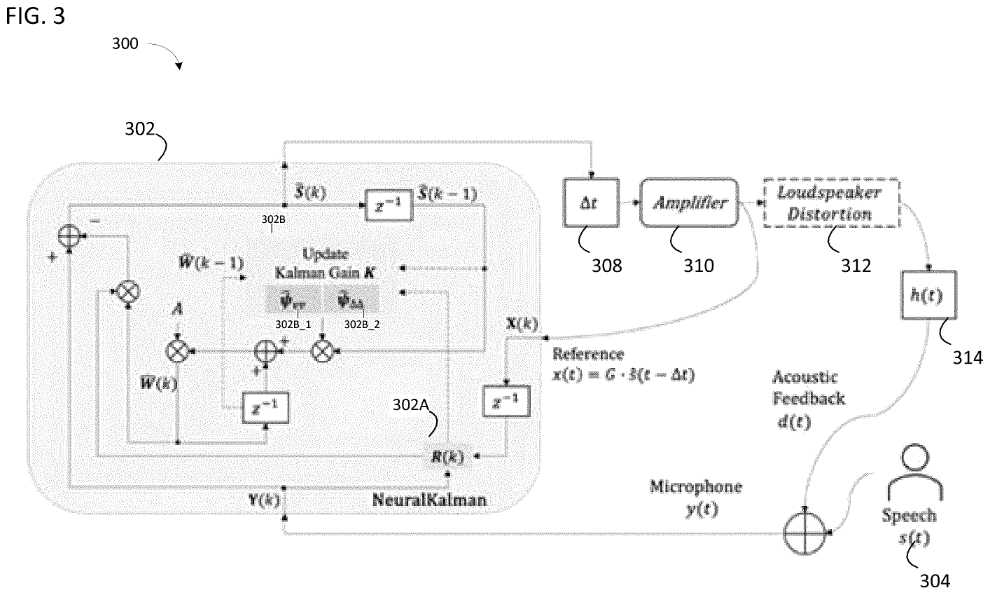

FIG. 3 shows an example of a single-channel acoustic amplification system 300 with the NeuralKalmanAHS model 302. The NeuralKalmanAHS model 302 may be implemented by one or more processors utilizing, for example, the processor illustrated in FIG. 2. In one or more examples, the NeuralKalmanAHS model 302 is implemented in the frequency domain. To clearly represent the relationships between all the signals, the signals outside of the NeuralKalmanAHS model are denoted using time-domain symbols. In one or more examples, the system includes a microphone that receives sound from a person 304 and a loudspeaker (e.g., amplifier 310), both of which are in the same space. The microphone may receive a mixture of the near-end speech signal s(t) as well as the playback signal d(t), and may send the mixed signal y(t) to the NeuralKalmanAHS model 302 for howling suppression. The output from the NeuralKalmanAHS model 302 may be amplified based on the designated loudspeaker gain, and the amplified output x(t) may be played out by the loudspeaker.

In one or more examples, the playback signal d(t) originated from x(t) may be formulated as follows.

$$d ( t ) = x ( t ) * h ( t ) , \qquad Eq . ( 1 )$$

where h(t) (314) represents the acoustic path from loudspeaker 310 to microphone, and * denotes linear convolution. The output of the loudspeaker 310 may contain distortions (e.g., loudspeaker distortion 312).

Without the NeuralKalmanAHS model 302, the microphone signal may be formulated as follows.

$$y ( t ) = s ( t ) + [ y ( t - Δ t ) \cdot G ] * h ( t ) , \qquad Eq . ( 2 )$$

where G is the loudspeaker gain and Δt denotes the delay between the microphone and the loudspeaker introduced by the system. The recursive relation in Eq. (2) leads to a re-amplifying of the playback signal, which results in acoustic howling (e.g., a high-pitched jarring sound).

With the NeuralKalmanAHS model 302, the microphone signal may be formulated as follows:

$$y ( t ) = s ( t ) + [ \hat{s} ( t - Δ t ) \cdot G ] * h ( t ) , \qquad Eq . ( 3 )$$

where \hat{ }s(t) is the output from the NeuralKalmanAHS model 302. In one or more examples, the estimated \hat{ }s(t) will be as close as possible to s(t). Since acoustic howling is a recursive process, the robustness of the NeuralKalmanAHS model 302 is measured by the amount of howling sound that is removed in each iteration.

While acoustic howling and acoustic echo share origins in feedback within communication systems, these two phenomena represent distinct issues for two reasons. First, while both phenomena stem from playback signals, howling involves recursively accumulated and re-amplified playback signals. Second, in acoustic howling scenarios, the playback signal originates from the same near-end speaker (e.g., speaker and amplifier are in proximity of each other), thereby making AHS more challenging.

According to one or more embodiments, a Frequency-domain Kalman filter (FDKF) estimates the feedback signal by modeling the acoustic path with an adaptive filter W(k) (e.g., k denotes the frame index). FDKF may be implemented as a two-step process, where the iterative feedback from these steps drives the update of filter weights.

In a prediction step, the near-end signal S(k) may estimated by a measurement equation as follows.

$$\hat{S} ( k ) = Y ( k ) - X ( k ) \hat{W} ( k ) , \qquad Eq . ( 4 )$$

where Ŝ(k), Y(k), and X(k) are the short-time Fourier transform (STFT) of the estimated target speech, microphone, and reference signal, respectively. In one or more examples, for Kalman filtering, the loudspeaker signal X(k) may be utilized as R(k). An inverse, STFT may be applied on Ŝ(k) to obtain the time-domain ŝ(t). Ŵ(k) denotes the estimated echo path in the frequency domain.

In the update step, the state equation for updating echo path Ŵ(k) may be defined as follows:

$$\hat{W} ( k + 1 ) = A [ \hat{W} ( k ) + K ( k ) \hat{S} ( k ) ] , \qquad Eq . ( 5 )$$

where A is the transition factor. K(k) may denote the Kalman gain. As illustrated in FIG. 3, K(k) is related to far-end signal X(k), echo path Ŵ(k−1) and estimated near-end signal Ŝ(k−1). The dash line in the NeuralKalmanAHS model 302 may indicate indirect relations

The calculation of K(k) may be defined as follows:

$$K ( k ) = P ( k ) {{X}^{H} ( k ) [ X ( k ) P ( k ) {X}^{H} ( k ) + {Ψ}_{v v} ( k ) ]}^{- 1} , \qquad Eq . ( 6 )$$

$$P ( k + 1 ) = {A}^{2} [ I - \frac{1}{2} K ( k ) X ( k ) ] P ( k ) + {Ψ}_{Δ Δ} ( k ) , \qquad Eq . ( 7 )$$

where P(k) is the state estimation error covariance. The matrices Ψᵥᵥ(k) and Ψ_{ΔΔ}(k) may correspond to observation noise covariance and process noise covariance, respectively, and may be approximated by the covariance of the estimated near-end signal Ψ_{ŝŝ}(k) and the echo-path Ψ_{ŴŴ}(k), respectively.

In Kalman filtering, these matrices may be determined as follows.

$${Ψ}_{v v} ( k + 1 ) = 0.9 {Ψ}_{v v} ( k ) + 0.1 {\vert \hat{S} ( k ) \vert}^{2} , \qquad Eq . ( 8 )$$

$${Ψ}_{Δ Δ} ( k + 1 ) = 0.9 {Ψ}_{Δ Δ} ( k ) + 0.1 ( 1 - {A}^{2} ) {\vert \hat{W} ( k ) \vert}^{2} . \qquad Eq . ( 9 )$$

FIG. 3 illustrates an example structure of the NeuralKalmanAHS model 302, where the frequency-domain Kalman filter is enhanced by integrating NN components to refine the reference signal X(k) and covariance matrices Ψᵥᵥ(k) and Ψ_{ΔΔ}(k). In one or more examples, the NeuralKalmanAHS 302 includes a NN 302A that refines a reference signal. In one or more examples, the NeuralKalmanAHS model 302 includes a module 302B that updates a Kalman Gain K. The module 302B may include NN 302B_1 for refining Ψᵥᵥ(k) and NN 302B_2 for refining Ψ_{ΔΔ}(k). Each of NN 302A, NN 302B_1, and NN 302C_1 may be implemented by different processors or the same processor. Each of NN 302A, NN 302B_1, and NN 302C_1 may be the same type of neural network or different networks.

According to one or more embodiments, to enhance adaptive algorithm capabilities, an original reference signal may be refined (e.g., modified) by incorporating a learned reference signal. In one or more examples, a learned reference signal R(k) may be integrated into the Kalman filter framework, with the original reference signal X(k−1) and microphone recording Y(k) provided as inputs as follow.

$$R ( k ) = {ℋ}_{r} ( Y ( k ) , X ( k - 1 ) ) , \qquad Eq . ( 10 )$$

where [symbol] ᵣ represents the network parameters for reference signal estimation.

In one or more examples, [symbol] ᵣ may be designed as a two-layer long short-term memory (LSTM) network with 300 units per layer followed by a linear layer with a Sigmoid activation function, which may take the concatenation of the log power spectrums of the original reference signal and microphone recording as input and estimates a ratio mask. The estimated ratio mask may then be applied to the microphone signal to produce the refined reference signal R(k). By integrating this refined reference signal into the Kalman filter, the operational load on the Kalman filter, particularly in attenuating severe acoustic howling, is significantly reduced, thereby enhancing the efficiency of the Kalman filter.

In the Kalman filter, covariance matrices Ψᵥᵥ(k) and Ψ_{ΔΔ}(k) may represent uncertainties associated with measurement and state variables. The accuracy of an estimation of the covariance matrices significantly influences the performance of the Kalman filter, affecting state estimation accuracy, adaptation to dynamic conditions, and convergence rate, which is crucial for dependable AHS. Conventional methods for covariance matrix estimation in the Kalman filter often assume linearity and stationary conditions, neglecting variable interdependencies and being sensitive to noise and outliers, limiting adaptability and prediction accuracy.

In one or more examples, NN modules are utilized to learn the covariance matrices of the Kalman filter. In one or more examples, the original estimations in equations (9) and (10) are transformed as follows in equations (11) and (12), respectively.

$${Ψ}_{v v} ( k ) = {ℋ}_{Ψ 1} ( \hat{S} ( k ) ) , \qquad Eq . ( 11 )$$

$${Ψ}_{Δ Δ} ( ( k ) = {ℋ}_{Ψ 2} ( \hat{W} ( k ) ) ) , \qquad Eq . ( 12 )$$

where the estimation of Ψ_{VV}(k) and ΨΔΔ(k) both involve training an LSTM cell with 65 hidden states. The inputs to the RNNs for estimating Ψ_{VV}(k) and ΨΔΔ(k) are the magnitude of estimated near-end speech \hat{ }S(k) and \hat{ }W(k), respectively. Eq. (11) may be implemented by the NN 302B_1 and Eq. (12) may be implemented by the NN 302B_2.

The loss function in Eq. (11) may rely on a L1 norm to quantify a difference in magnitude spectrum between the enhanced signal \hat{ }S and the target signal S. By utilizing the L1 loss on the magnitude spectrum, the NeuralKalmanAHS model 302 benefits from effective regularization of the scale of the output signal.

$$Loss = l 1 ( S , \hat{S} ) \qquad Eq . ( 13 )$$

Applicant has observed that training of the NeuralKalmanAHS model 302 may be difficult during sever acoustic howling. Furthermore, severe acoustic howling is prone to occur with an initially randomized model. The recursive nature of streaming training may result in an energy explosion, leading to a ‘not a number’ (NAN) issue and halting of gradient updates. In this regard, training the NeuralKalmanAHS model 302 during sever acoustic howling may degrade the performance of the NeuralKalmanAHS model 302.

In one or more examples, during training NeuralKalmanAHS model 302, howling detection may be implemented. For examples, during each training iteration, the output of the NeuralKalmanAHS model 302 is monitored based on a normalized scale of approximately −1.0 to +1.0 to interpret a 16-bit WAV file containing amplitudes of the output of the NeuralKalmanAHS model 302. If the amplitude surpasses the upper limit for over 100 consecutive samples (e.g., a threshold set from experimental observations), training is halted to prevent howling. This strategy advantageously prevents the recursive training from triggering NAN issues, thereby preventing gradient update failures and enhancing the convergence of the model. In one or more examples, the proposed model is trained for 60 epochs with a batch size of 128.

The embodiments of the present disclosure provide NeuralKalmanAHS model, which may include an NN augmented Kalman filter for acoustic howling suppression. The embodiments of the present disclosure employs NN to help refine reference signal and estimate covariance matrices in the frequency-domain Kalman filter. Through an ablation study, Applicant has observed that modeling the reference signal helps improve howling suppression performance compared to a traditional Kalman filter based method. Furthermore, using NN for accurate estimation of covariance matrices also achieves improved howling suppression performance. Furthermore, jointly modeling the reference signal and the covariance matrices results in the best overall performance.

The NeuralKalmanAHS model according to the embodiments of the present disclosure outperforms strong DNN-based benchmarks and exhibits less distortion.

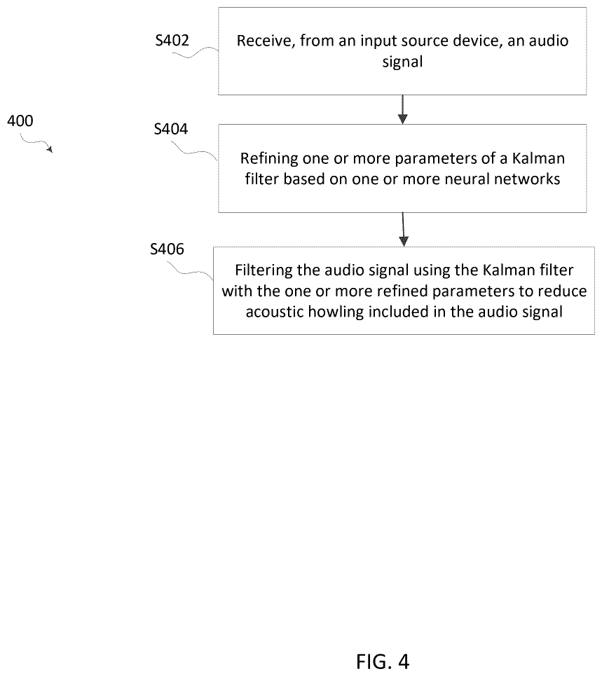

FIG. 4 illustrates a flowchart of an example process 400 for implementing the NeuralKalman AHS model, according to one or more embodiments.

The process starts at operation S402 where an audio signal is received from an input source device. For example, the audio signal y(t) may be received from a person speaking into a microphone. The audio signal y(t) may include acoustic howling based on the microphone being in a same space as a loudspeaker or amplifier.

The process proceeds to operation S404 where one or more parameters of a Kalman filter are refined based on one or more neural networks. For example, a first neural network may refine an original reference signal to generate a learned reference signal R(k). A second neural network may refine an estimation of the observation covariance matrix Ψ_{VV}(k). A third neural network may refine an estimation of the process noise covariance matrix ΨΔΔ(k).

The process proceeds to operation S406 where the audio signal is filtered using the Kalman filter with the one or more refined parameters to reduce acoustic howling included in the audio signal.

The proposed methods disclosed herein may be implemented by processing circuitry (e.g., one or more processors or one or more integrated circuits). In one example, the one or more processors execute a program that is stored in a non-transitory computer-readable medium to perform one or more of the proposed methods.

The techniques described above may be implemented as computer software using computer-readable instructions and physically stored in one or more computer-readable media.

Embodiments of the present disclosure may be used separately or combined in any order. Further, each of the embodiments (and methods thereof) may be implemented by processing circuitry (e.g., one or more processors or one or more integrated circuits). In one example, the one or more processors execute a program that is stored in a non-transitory computer-readable medium.

The foregoing disclosure provides illustration and description, but is not intended to be exhaustive or to limit the implementations to the precise form disclosed. Modifications and variations are possible in light of the above disclosure or may be acquired from practice of the implementations.

As used herein, the term component is intended to be broadly construed as hardware, firmware, or a combination of hardware and software.

Even though combinations of features are recited in the claims and/or disclosed in the specification, these combinations are not intended to limit the disclosure of possible implementations. In fact, many of these features may be combined in ways not specifically recited in the claims and/or disclosed in the specification. Although each dependent claim listed below may directly depend on only one claim, the disclosure of possible implementations includes each dependent claim in combination with every other claim in the claim set.

No element, act, or instruction used herein should be construed as critical or essential unless explicitly described as such. Also, as used herein, the articles “a” and “an” are intended to include one or more items, and may be used interchangeably with “one or more.” Furthermore, as used herein, the term “set” is intended to include one or more items (e.g., related items, unrelated items, a combination of related and unrelated items, etc.), and may be used interchangeably with “one or more.” Where only one item is intended, the term “one” or similar language is used. Also, as used herein, the terms “has,” “have,” “having,” or the like are intended to be open-ended terms. Further, the phrase “based on” is intended to mean “based, at least in part, on” unless explicitly stated otherwise.

The above disclosure also encompasses the embodiments listed below:

(1) A method performed by at least one processor of an acoustic howling suppression (AHS) system, the method including: receiving, from an input source device, an audio signal; refining one or more parameters of a Kalman filter based on one or more neural networks; and filtering the audio signal using the Kalman filter with the one or more refined parameters of the Kalman filter to reduce acoustic howling included in the audio signal.

(2) The method according to feature (1), in which the one or more parameters comprises a reference signal of the Kalman filter, and in which the one or more neural networks includes a first neural network that refines the reference signal of the Kalman filter based on the audio signal to generate a learned reference signal.

(3) The method according to feature (2), in which the learned reference signal is generated based on a two-layer long short-term memory (LSTM) network applied to the audio signal and the reference signal of the Kalman filter.

(4) The method according to feature (2) or (3), in which the one or more parameters includes an observation covariance matrix estimation, and in which the one or more neural networks includes a second neural network that refines the observation covariance matrix estimation using the learned reference signal of the Kalman filter.

(5) The method according to feature (4), in which the observation matrix estimation is generated based on a two-layer short-term memory (LSTM) network applied to an output of the Kalman filter.

(6) The method according to feature (4) or (5), in which the one or more parameters includes a noise covariance estimation, and in which the one or more neural networks includes a third neural network that refines the noise covariance estimation using the learned reference signal of the Kalman filter.

(7) The method according to feature (6), in which noise covariance estimation is generated based on a two-layer short-term memory (LSTM) network applied to an echo path.

(8) The method according to any one of features (1)-(7), further including: determining whether acoustic howling is detected in the audio signal; and based on a determination that the acoustic howling is detected, stopping training of the one or more neural networks.

(9) The method according to any one of features (1)-(8), in which the acoustic howling is detected based on a determination that an amplitude of an output of the Kalman filter signal exceeds an amplitude threshold for a predetermined period.

(10) The method according to any one of features (1)-(9), in which the input source device is a microphone that receives first audio from a user of the microphone and second audio from an amplifier.

(11) An acoustic howling suppression (AHS) system, including: at least one memory configured to store program code; and at least one processor configured to read the program code and operate as instructed by the program code, the program code including: receiving code configured to cause the at least one processor to receive, from an input source device, an audio signal; refining code configured to cause the at least one processor to refine one or more parameters of a Kalman filter based on one or more neural networks; and filtering code configured to cause the at least one processor to filter the audio signal using the Kalman filter with the one or more refined parameters of the Kalman filter to reduce acoustic howling included in the audio signal.

(12) The system according to feature (11), in which the one or more parameters comprises a reference signal of the Kalman filter, and in which the one or more neural networks includes a first neural network that refines the reference signal of the Kalman filter based on the audio signal to generate a learned reference signal.

(13) The system according to feature (12), in which the learned reference signal is generated based on a two-layer long short-term memory (LSTM) network applied to the audio signal and the reference signal of the Kalman filter.

(14) The system according to feature (12) or (13), in which the one or more parameters includes an observation covariance matrix estimation, and in which the one or more neural networks includes a second neural network that refines the observation covariance matrix estimation using the learned reference signal of the Kalman filter.

(15) The system according to feature (14), in which the observation matrix estimation is generated based on a two-layer short-term memory (LSTM) network applied to an output of the Kalman filter.

(16) The system according to feature (14) or (15), in which the one or more parameters includes a noise covariance estimation, and in which the one or more neural networks includes a third neural network that refines the noise covariance estimation using the learned reference signal of the Kalman filter.

(17) The system according to feature (16), in which noise covariance estimation is generated based on a two-layer short-term memory (LSTM) network applied to an echo path.

(18) The system according to any one of features (11)-(17), in which the program code further includes: determining code configured to cause the at least one processor to determine whether acoustic howling is detected in the audio signal; and stopping code configured to cause the at least one processor to stop, based on a determination that the acoustic howling is detected, training of the one or more neural networks.

(19) The system according to feature (11)-(18), in which the acoustic howling is detected based on a determination that an amplitude of an output of the Kalman filter exceeds an amplitude threshold for a predetermined period.

(20) A non-transitory computer readable medium having instructions stored therein, which when executed by a processor in an acoustic howling suppression (AHS) system cause the processor to execute a method including: receiving, from an input source device, an audio signal; refining one or more parameters of a Kalman filter based on one or more neural networks; and filtering the audio signal using the Kalman filter with the one or more refined parameters of the Kalman filter to reduce acoustic howling included in the audio signal.

What is claimed is:

1. A method performed by at least one processor of an acoustic howling suppression (AHS) system, the method comprising:
receiving, from an input source device, an audio signal;
refining one or more parameters of a Kalman filter based on one or more neural networks; and
filtering the audio signal using the Kalman filter with the one or more refined parameters of the Kalman filter to reduce acoustic howling included in the audio signal.

2. The method according to claim 1, wherein the one or more parameters comprises a reference signal of the Kalman filter, and wherein the one or more neural networks includes a first neural network that refines the reference signal of the Kalman filter based on the audio signal to generate a learned reference signal.

3. The method according to claim 2, wherein the learned reference signal is generated based on a two-layer long short-term memory (LSTM) network applied to the audio signal and the reference signal of the Kalman filter.

4. The method according to claim 2, wherein the one or more parameters includes an observation covariance matrix estimation, and wherein the one or more neural networks includes a second neural network that refines the observation covariance matrix estimation using the learned reference signal of the Kalman filter.

5. The method according to claim 4, wherein the observation matrix estimation is generated based on a two-layer short-term memory (LSTM) network applied to an output of the Kalman filter.

6. The method according to claim 4, wherein the one or more parameters includes a noise covariance estimation, and wherein the one or more neural networks includes a third neural network that refines the noise covariance estimation using the learned reference signal of the Kalman filter.

7. The method according to claim 6, wherein noise covariance estimation is generated based on a two-layer short-term memory (LSTM) network applied to an echo path.

8. The method according to claim 1, further comprising:
determining whether acoustic howling is detected in the audio signal; and
based on a determination that the acoustic howling is detected, stopping training of the one or more neural networks.

9. The method according to claim 1, wherein the acoustic howling is detected based on a determination that an amplitude of an output of the Kalman filter signal exceeds an amplitude threshold for a predetermined period.

10. The method according to claim 1, wherein the input source device is a microphone that receives first audio from a user of the microphone and second audio from an amplifier.

11. An acoustic howling suppression (AHS) system, comprising:
at least one memory configured to store program code; and
at least one processor configured to read the program code and operate as instructed by the program code, the program code including:
receiving code configured to cause the at least one processor to receive, from an input source device, an audio signal;
refining code configured to cause the at least one processor to refine one or more parameters of a Kalman filter based on one or more neural networks; and
filtering code configured to cause the at least one processor to filter the audio signal using the Kalman filter with the one or more refined parameters of the Kalman filter to reduce acoustic howling included in the audio signal.

12. The system according to claim 11, wherein the one or more parameters comprises a reference signal of the Kalman filter, and wherein the one or more neural networks includes a first neural network that refines the reference signal of the Kalman filter based on the audio signal to generate a learned reference signal.

13. The system according to claim 12, wherein the learned reference signal is generated based on a two-layer long short-term memory (LSTM) network applied to the audio signal and the reference signal of the Kalman filter.

14. The system according to claim 12, wherein the one or more parameters includes an observation covariance matrix estimation, and wherein the one or more neural networks includes a second neural network that refines the observation covariance matrix estimation using the learned reference signal of the Kalman filter.

15. The system according to claim 14, wherein the observation matrix estimation is generated based on a two-layer short-term memory (LSTM) network applied to an output of the Kalman filter.

16. The system according to claim 14, wherein the one or more parameters includes a noise covariance estimation, and wherein the one or more neural networks includes a third neural network that refines the noise covariance estimation using the learned reference signal of the Kalman filter.

17. The system according to claim 16, wherein noise covariance estimation is generated based on a two-layer short-term memory (LSTM) network applied to an echo path.

18. The system according to claim 11, wherein the program code further includes:
determining code configured to cause the at least one processor to determine whether acoustic howling is detected in the audio signal; and
stopping code configured to cause the at least one processor to stop, based on a determination that the acoustic howling is detected, training of the one or more neural networks.

19. The system according to claim 11, wherein the acoustic howling is detected based on a determination that an amplitude of an output of the Kalman filter exceeds an amplitude threshold for a predetermined period.

20. A non-transitory computer readable medium having instructions stored therein, which when executed by a processor in an acoustic howling suppression (AHS) system cause the processor to execute a method comprising:
receiving, from an input source device, an audio signal;
refining one or more parameters of a Kalman filter based on one or more neural networks; and
filtering the audio signal using the Kalman filter with the one or more refined parameters of the Kalman filter to reduce acoustic howling included in the audio signal.
